(19) United States
(12) Patent Application Publication
(10) Pub. No.: US 2016/0248374 A1
(43) Pub. Date: Aug. 25, 2016

(54) PHOTOVOLTAIC SYSTEM

(71) Applicant: LSIS CO., LTD., Anyang-si (KR)

(72) Inventors: HWA YOUNG CHOI, Anyang-si (KR); CHOONG KUN CHO, Gunpo-si (KR)

(73) Assignee: LSIS CO., LTD., Anyang-si (KR)

(21) Appl. No.: 15/003,701

(22) Filed: Jan. 21, 2016

(30) Foreign Application Priority Data
Feb. 23, 2015 (KR) 10-2015-0025052

(51) Int. Cl. H02S 50/00; G01R 21/133

(52) U.S. Cl. CPC H02S 50/00; G01R 21/133

(57) ABSTRACT

A photovoltaic system is provided. A data collection device for the photovoltaic system includes a receiver receiving, from a photovoltaic device, generation that absorbed solar energy is converted into electrical energy, and photovoltaic power generation related information, a control unit determining estimated generation based on the photovoltaic power generation related information received from the receiver, and determining a specific value based on the estimated generation and received actual generation, a storage unit storing photovoltaic power generation data that includes the generation and the photovoltaic power generation related information, and a transmitter transmitting, to an external device, the specific value determined by the control unit and the photovoltaic power generation related information.

### CROSS-REFERENCE TO RELATED APPLICATIONS

Pursuant to 35 U.S.C. §119(a), this application claims the benefit of earlier filing date and right of priority to Korean Patent Application No. 10-2015-0025052, filed on Feb. 23, 2015 the contents of which are hereby incorporated by reference herein in its entirety.

### BACKGROUND

The present disclosure relates to a photovoltaic system, and particularly to, a method that monitors a photovoltaic value.

Due to worries about the exhaustion of fossil energy, such as oil and environmental pollution, interest in alternative energy increases. Among others, photovoltaic power generation that uses solar energy to produce electricity on a large scale by spreading, on a large scale, panels to which solar batteries are attached. The photovoltaic power generation has advantages in that there is no need to consume fuel costs and there is no air pollution or waste, because it uses unlimited, pollution-free solar energy.

A solar energy power generation style includes an independent style and a system-associated style. In the system-associated style, a photovoltaic device is connected to a typical power system. When a photovoltaic system generates electricity in daytime, it transmits power and at night or when it rains, the photovoltaic power generation system receives electricity from a system. In order to efficiently use the system-associated photovoltaic system, a photovoltaic system has been introduced which stores idle power in a battery energy storage system (BESS) under a light load, and discharges the BESS to supply discharged power as well as photovoltaic power to the system under a heavy load.

### SUMMARY

Embodiments provide a photovoltaic system that minimizes an amount of data that a data collection device has to deliver to a higher server, through estimated generation according to sunshine information, based on the empirical rule that photovoltaic generation almost matches insolation information.

In one embodiment, a data collection device includes a receiver receiving, from a photovoltaic device, generation that absorbed solar energy is converted into electrical energy, and photovoltaic power generation related information, a control unit determining estimated generation based on the photovoltaic power generation related information received from the receiver, and determining a specific value based on the estimated generation and received actual generation, a storage unit storing photovoltaic power generation data that includes the generation and the photovoltaic power generation related information, and a transmitter transmitting, to an external device, the specific value determined by the control unit and the photovoltaic power generation related information.

The control unit may determine estimated generation from the photovoltaic power generation data accumulated tin the storage based on any one of insolation information and temperature information that are included in the photovoltaic power generation related information.

The storage unit may store accumulated generation data that includes insolation data and generation data corresponding to the insolation data, and the control unit may determine, as estimated generation, photovoltaic generation corresponding to the photovoltaic power generation related information among the accumulated generation data.

The control unit may compare the photovoltaic power generation related information and the insolation data that is stored in the storage unit, and determine, as estimated generation, generation data corresponding to closest insolation data.

The control unit may determine, as the specific value, a difference between the received actual generation and estimated generation.

The data collection device may further include an output unit that displays the determined estimated generation and the received actual generation.

The control unit may transmit a whole of the actual generation to the external device through the transmitter, when a difference between the determined estimated generation and the received actual generation is equal to or larger than a specific value.

In another embodiment, a photovoltaic system includes a photovoltaic device absorbing and converting solar energy into electrical energy, a data collection device determining estimated generation based on photovoltaic power generation related information received from the photovoltaic device, and determining a specific value based on the estimated generation and received actual generation, and an external device determining photovoltaic generation based on the photovoltaic power generation related information and the specific value that are received from the data collection device.

The external device may estimate photovoltaic generation based on the photovoltaic power generation related information received from the data collection device, and calculate the estimated photovoltaic generation and the specific value to determine photovoltaic generation.

The data collection device may deliver a whole of photovoltaic generation received from the photovoltaic device to the external device, when the specific value has a size equal to or larger than a certain value.

The data collection device may determine, as estimated generation, fundamental generation according to set region information.

### BRIEF DESCRIPTION OF THE DRAWINGS

FIG. 1 is a block diagram of a system-associated photovoltaic device according to an embodiment.

FIG. 2 is a block diagram of a small-scale system-associated photovoltaic device according to an embodiment.

FIG. 3 is a flowchart of the operation of a system-associated photovoltaic device according to an embodiment.

FIG. 4 is a block diagram of a system-associated photovoltaic device according to another embodiment.

FIG. 5 is a block diagram that represents the configuration of a photovoltaic system.

FIG. 6 is a block diagram that represents the configuration of a data collection device.

FIG. 7 is a flowchart of the process of transmitting/receiving data for monitoring in a photovoltaic system according to an embodiment.

FIG. 8 is a graph that represents how a data collection device typically delivers photovoltaic generation to a higher server.

FIG. 9 is a graph that represents how a data collection device delivers photovoltaic generation to a higher server according to an embodiment.

FIG. 10 is a diagram that represents daily generation in a table.

FIGS. 11 to 13 are graphs that compare the above-described transmission method with a typical method.

### DETAILED DESCRIPTION OF THE EMBODIMENTS

Embodiments are described below in detail with reference to the accompanying drawings so that a person skilled in the art may easily practice the embodiments. However, the present disclosure may be implemented in many different forms and is not limited to embodiments that are described herein. In addition, parts irrelevant to descriptions are not provided in the drawings in order to make the present disclosure clear and similar parts throughout the disclosure have similar reference numerals.

Also, when it is described that a part includes some components, it should be understood that it may not exclude but further include other components if there is no specific objection.

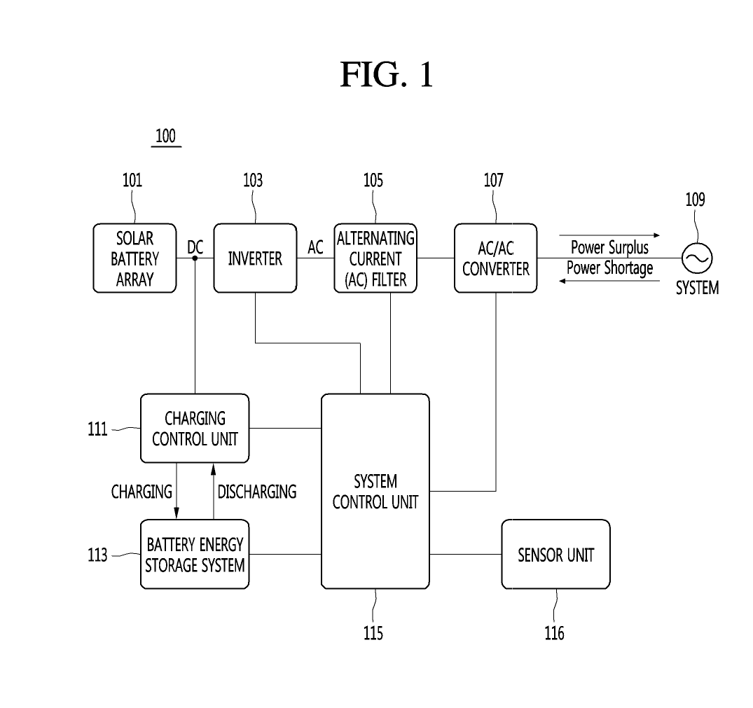

In the following, a system-associated photovoltaic device according to an embodiment is described with reference to FIGS. 1 to 3.

FIG. 1 is a block diagram of a system-associated photovoltaic device according to an embodiment.

A system-associated photovoltaic device 100 according to an embodiment includes a solar battery array 101, an inverter 103, an alternating current (AC) filter 105, an AC/AC converter 107, a system 109, a charging control unit 111, a battery energy storage system 113, a system control unit 115, and a sensor unit 116.

The solar battery array 101 is obtained by coupling a plurality of solar battery modules. The solar battery module is a device in which a plurality of solar batteries is connected in series or parallel to convert solar energy into electrical energy to generate a certain voltage and current. Thus, the solar battery array 101 absorbs solar energy to convert it into electrical energy.

The inverter 103 inverts direct current (DC) power into AC power. It receives the DC power supplied by the solar battery array 101 or the DC power discharged by the battery energy storage system 113 through the charging control unit 111 to invert them into AC power.

The AC filter 105 filters the noise of power inverted into the AC power.

The AC/AC converter 107 converts the size of a voltage of the AC power devoid of noise, and supplies the converted power to the system 109.

The system 109 is a system that incorporates many power stations, substations, power transmission and distribution cables, and loads to generate and use power.

The charging control unit 111 controls the charging and discharging of the battery energy storage system 113. When the system is a heavy load, the charging control unit 111 receives power from the battery energy storage system 113 and delivers it to the system. When the system is a light load, the charging control unit 111 receives power from the solar battery array 101 and delivers it to the battery energy storage system 113.

The battery energy storage system 113 receives electrical energy from the solar battery array 101 for charging and discharges the charged electrical energy according to the power supply and demand condition of the system 109. In particular, in the case that the system 109 is a light load, the battery energy storage system 113 receives idle power from the solar battery array 101 for charging. When the system 109 is a heavy load, the battery energy storage system 113 discharges charged power to supply power to the system 109. The power supply and demand condition of the system has a big difference according to the time zone. Thus, it is inefficient that the system-associated photovoltaic device 100 uniformly supplies the power supplied by the solar battery array 101 without consideration of the power supply and demand condition of the system 109. Therefore, the system-associated photovoltaic device 100 uses the battery energy storage system 113 to adjust an amount of power supply according to the power supply and demand of the system 109. Accordingly, the system-associated photovoltaic device 100 may efficiently supply power to the system 109.

The system control unit 115 controls the operations of the charging control unit 111, the inverter 103, the AC filter 105, and the AC/AC converter 107.

The sensor unit 116 senses other elements related to photovoltaic power generation. In this case, the sensor unit 116 may include any one of a sunshine sensor and a temperature sensor. In a particular embodiment, the sensor unit 116 may sense sunshine while photovoltaic power generation is performed. In another embodiment, the sensor unit 116 may sense temperature while photovoltaic power generation is performed.

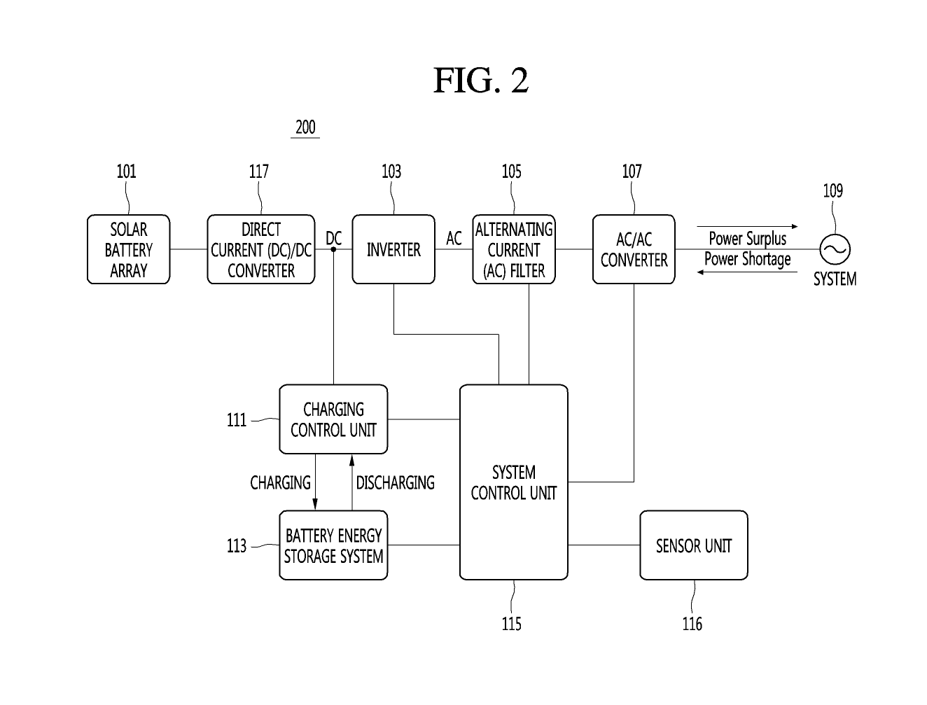

FIG. 2 is a block diagram of a small-capacity system-associated photovoltaic device according to an embodiment.

A small-capacity system-associated photovoltaic device 200 according to an embodiment includes a solar battery array 101, an inverter 103, an AC filter 105, an AC/AC converter 107, a system 109, a charging control unit 111, a battery energy storage system 113, a system control unit 115, a sensor unit 116, and a DC/DC converter 117.

The present embodiment is the same as the embodiment in FIG. 1 but further includes the DC/DC converter 117. The DC/DC converter 117 converts the voltage of DC power generated by the solar battery array 101. The voltage of power produced by the solar battery array 101 in the small-capacity system-associated photovoltaic device 200 is low. Thus, there is a need to boost the voltage in order to input power supplied by the solar battery array 101 to the inverter. The DC/DC converter 117 converts the voltage of power produced by the solar battery array 101 into a voltage that may be input to the inverter 103.

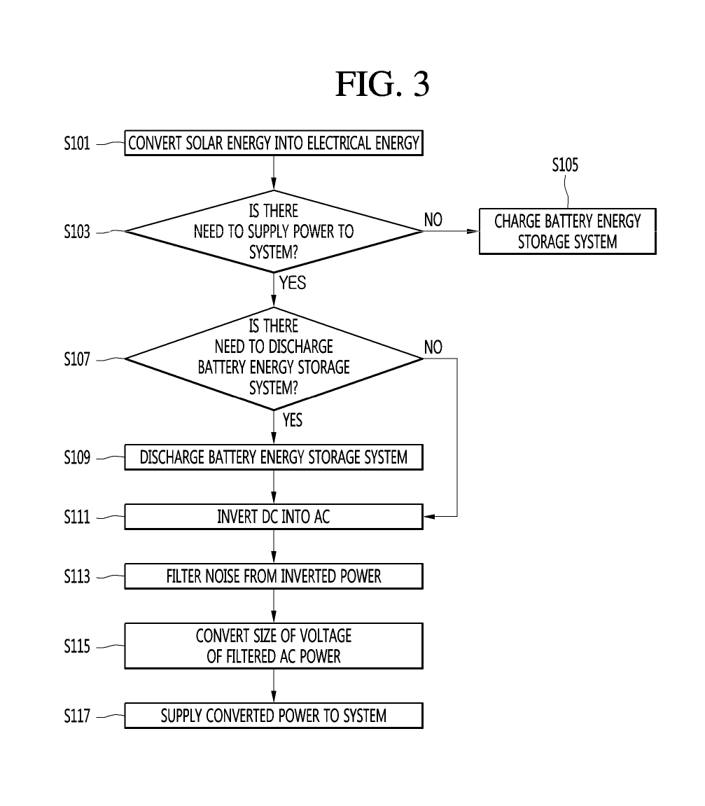

FIG. 3 is a flowchart of the operation of a system-associated photovoltaic device according to an embodiment.

The solar battery array 101 converts solar energy into electrical energy in step S101.

The system control unit 115 determines whether there is a need to supply power to the system 109, in step S103. Whether there is a need to supply power to the system 109 may be determined based on whether the system 109 is a heavy load or light load.

When there is no need to supply power to the system 109, the system control unit 115 controls the charging control unit 111 to charge the battery energy storage system 113, in step S 105. In particular, the system control unit 115 may generate a control signal that controls the charging control unit 111. The charging control unit 111 may receive the control signal to charge the battery energy storage system 113.

The system control unit 115 determines whether there is a need to discharge the battery energy storage system 113, in step S 107. It is possible to determine whether there is a need to discharge the battery energy storage system 113 because electrical energy supplied by the solar battery array 101 fails to satisfy the power demand of the system 109. Also, the system control unit 115 may determine whether the battery energy storage system 113 stores sufficient electrical energy to be discharged.

When there is a need to discharge the battery energy storage system 113, the system control unit 115 controls the charging control unit 111 to discharge the battery energy storage system 113, in step S109. In particular, the system control unit 115 may generate a control signal that controls the charging control unit 111. The charging control unit 111 may receive the control signal to discharge the battery energy storage system 113.

The inverter 103 inverts electrical energy discharged by the battery energy storage system 113 and electrical energy converted by the solar battery array 101 into AC, in step S111. In this case, the system-associated photovoltaic device 100 inverts both the electrical energy discharged by the battery energy storage system 113 and the electrical energy converted by the solar battery array 101 through a single inverter 103. Each electric appliance has a limit in consumption power. The limit includes an instantaneous limit and a long-term limit, and maximum power that may be used without damage to a device for a long time is defined as rated power. In order to maximize the efficiency of the inverter 103, there is a need to supply power so that the battery energy storage system 113 and the solar battery array 101 use power corresponding to 40% to 60% of the rated power.

The AC filter 105 filters the noise of inverted power, in step S113.

The AC/AC converter 107 converts the size of a voltage of the filtered AC power to supply the converted power to the system 109, in step S 115.

The system-associated photovoltaic device 100 supplies converted power to the system in step S117.

Since the system-associated photovoltaic device 100 according to the embodiments in FIGS. 1 to 3 uses only a single inverter 103, there are following limitations when the rated power of the inverter 103 is determined based on the capacity of the solar battery array 101 in order to design the system-associated photovoltaic device 100. When the battery energy storage system 113 discharges electricity and thus supplies electrical energy along with the solar battery array 101, it is difficult to maximize the efficiency of the inverter 103 because the inverter 103 uses power exceeding 40% to 60% of the rated power. Alternatively, when the battery energy storage system 113 discharges electricity and thus supplies electrical energy solely, it is difficult to maximize the efficiency of the inverter 103 because the inverter 103 uses power less than 40% to 60% of the rated power. Besides, when the battery energy storage system 101 supplies a little amount of electrical energy, it is difficult to maximize the efficiency of the inverter 103 because the inverter 103 uses power less than 40% to 60% of the rated power. In this case, the efficiency with which the system-associated photovoltaic device 100 converts solar energy into electrical energy decreases. Also, since the total harmonic distortion (THD) of power increases, the quality of power that the system-associated photovoltaic device 100 produces goes down.

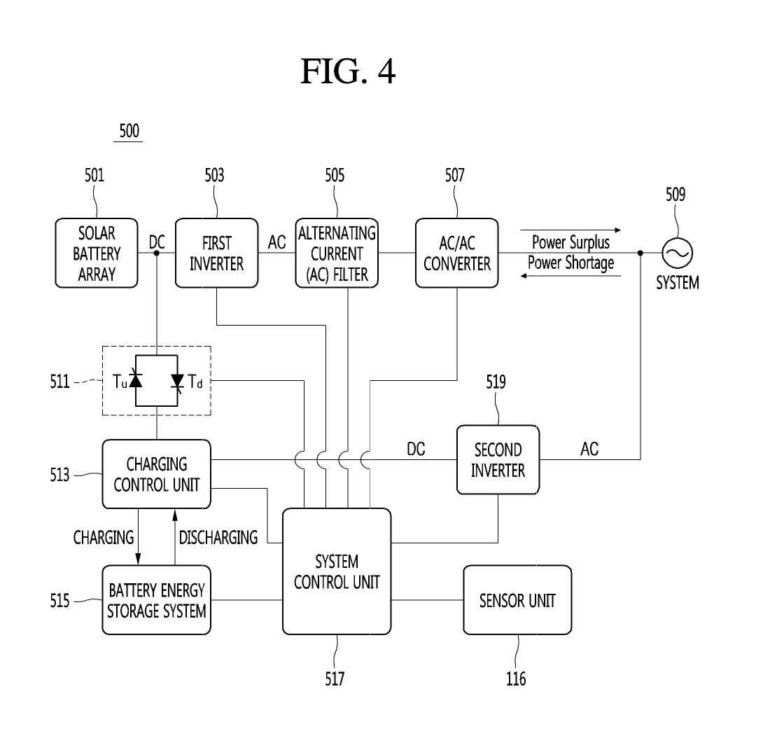

FIG. 4 is a block diagram of a system-associated photovoltaic device according to another embodiment.

A system-associated photovoltaic device 500 according to another embodiment includes a solar battery array 501, a first inverter 503, an AC filter 505, an AC/AC converter 507, a system 509, a control switch 511, a charging control unit 513, a battery energy storage system 515, a system control unit 517, and a second inverter 519. Also, it is possible to further include a sensor unit 116.

The solar battery array 501 is obtained by the coupling of a plurality of solar battery modules. The solar battery module is a device in which a plurality of solar batteries is connected in series or parallel to convert solar energy into electrical energy to generate a certain voltage and current. Thus, the solar battery array 501 absorbs solar energy to convert it into electrical energy.

The first inverter 503 inverts DC power into AC power. It receives the DC power from the solar battery array 501 or the DC power discharged by the battery energy storage system 515 through the charging control unit 513 to invert them into AC power.

The AC filter 505 filters the noise of power inverted into the AC power.

In order to be capable of supplying AC power to the system, the AC/AC converter 507 converts the size of a voltage of the AC power devoid of noise and supplies the converted power to the system 509.

The system 509 is a system that incorporates many power stations, substations, power transmission and distribution lines, and loads to generate and use power.

The control switch 511 adjusts the flow of power supply between the battery energy storage system 515 and the first inverter 503. The control switch 511 receives a control signal from the system control unit 517 to operate according to the control signal. In particular, when the battery energy storage system 515 discharges electricity to supply power to the first inverter 503, the system control unit 517 generates a control signal that connects the control switch 511 and the first inverter 503. The control switch 511 receives the control signal to connect the charging control unit 513 and the first inverter 503. When power is not supplied to the first inverter 503, the system control unit 517 generates a control signal that disconnects the control switch 511 from the first inverter. The control switch 511 receives the control signal to be disconnected from the first inverter 503.

The charging control unit 513 controls the charging and discharging of the battery energy storage system 515. When the system is a heavy load, the charging control unit 513 receives power from the battery energy storage system 515 and delivers it to the system. In this case, the charging control unit 513 may supply power to any one of the first inverter or the second inverter 519 or to both the first inverter 503 and the second inverter 519. When the system is a light load, the charging control unit 513 receives power from the solar battery array 501 and delivers it to the battery energy storage system 515.

When the system is a light load, the battery energy storage system 515 receives and charge idle power from the solar battery array 501. When the system is a heavy load, the battery energy storage system 515 discharges charged power to supply power to the system 509. As described in the embodiments in FIGS. 1 to 3, the system-associated photovoltaic device 500 may use the battery energy storage system 515 to efficiently power to the system 509.

The system control unit 517 controls the operations of the charging control unit 513, the first inverter 503, the second inverter 519, the AC filter 505, and the AC/AC converter 507.

Unlike the embodiments in FIGS. 1 to 3, the embodiment in FIG. 4 further includes the second inverter 519 that is connected to the battery energy storage system 515.

The second inverter 519 inverts DC power into AC power. It receives the DC power discharged by the battery energy storage system 515 through the charging control unit 513 and inverts the received DC power into AC power. By including the second inverter 519 besides the first inverter 503, the first inverter or the second inverter selectively operates according to the size of power supplied by the system-associated photovoltaic device 500.

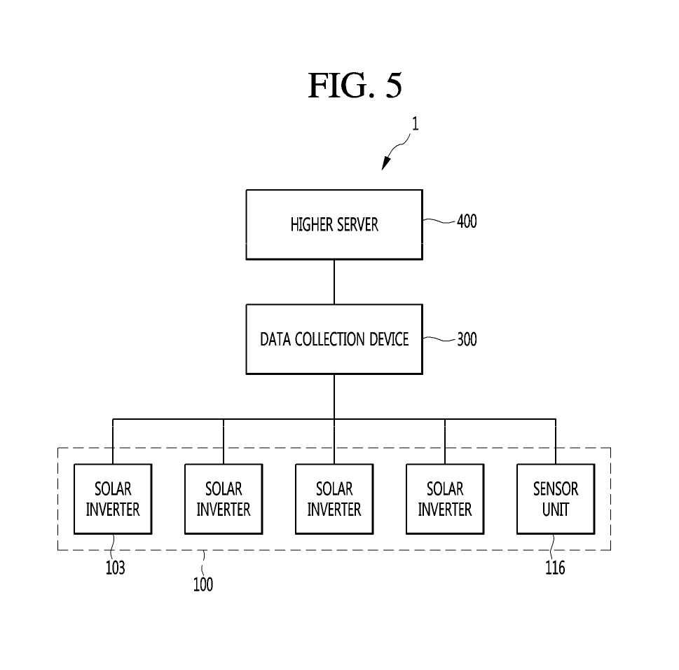

FIG. 5 is a block diagram that represents the configuration of the photovoltaic system 1.

Referring to FIG. 5, a solar inverter 103 may be included in the photovoltaic device 100. Since the solar inverter 103 has been described above in detail, related descriptions are omitted in FIG. 4. The solar inverter 103 may exist in singularity or in plurality in the photovoltaic device 100. The photovoltaic inverter 103 may deliver photovoltaic generation to a data collection device 300.

Various sensors of the sensor unit 116 of the photovoltaic device 100 may deliver sensed data along with the photovoltaic generation to the data collection device 300. In an embodiment, the sensed data may include at least one of sunshine, temperature, sunrise/sunset time, and a weather condition. The photovoltaic device may deliver power generation time information along with the above-described data to the data collection device 300.

The data collection device 300 receives and synthesizes data from the lower inverter 103 and the photovoltaic device 100. The data collection device 300 may be a component in the photovoltaic device 100 or may be a separate component that is connected to a plurality of photovoltaic devices 100. The data collection device 300 may provide the collected power generation information to users or clients for monitoring. Also, when there is a higher server 400 connected to the plurality of data collection devices 300, it is possible to deliver the collected power generation information to the higher server 400.

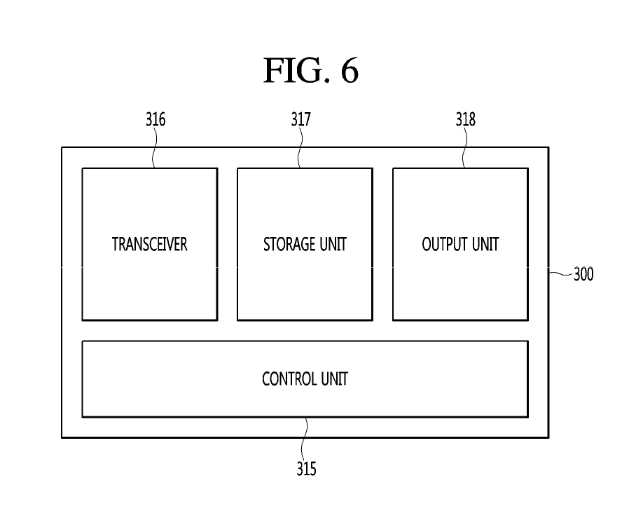

In the following, the data collection device 300 is described in detail with reference to FIG. 6.

The data collection device 300 may include a control unit 315, a transceiver 316, a storage unit 317, and an output unit 318, as shown in FIG. 5. However, the embodiment is not limited to components in FIG. 5 and may further include other components as needed.

The transceiver 316 receives photovoltaic related data from the photovoltaic device 100 that includes the inverter 103 and various sensors (not shown). A reception method may include both wired and wireless communication methods. When the data collection device 300 is a component in the photovoltaic device 100, it is possible to receive data through a circuit that is connected to between internal components.

Also, the transceiver 316 may transmit the collected photovoltaic power generation data to the higher server 400. Likewise, it is possible to transmit the data to the higher server 400 through wired/wireless communication.

Also, the transceiver 316 may transmit the photovoltaic generation to users and clients. In particular, it is possible to transmit information for monitoring the generation to the owner of the photovoltaic device 100 or to an electricity dealer.

The storage unit 317 stores collected power generation data. Photovoltaic power generation is performed everyday, and the data collected by the data collection device 300 is stored in the storage unit 317 for the time being and transmitted to another place. The data stored in the storage unit 317 may be utilized for decreasing transmission data to be described below.

The output unit 318 may display data for monitoring the photovoltaic generation. The output unit may include a display that visually displays data, and a speaker that auditorily outputs data.

The control unit 315 controls the operations of the above-described transceiver 316, storage unit 317, and output unit 318. Furthermore, the control unit 315 may process the received data to generate difference data. How to process the data is described below in detail.

Refer back to FIG. 5.

The photovoltaic system 1 may include the high-level server 400 to which the plurality of data collection devices 300 are connected. The high-level server 400 may synthesize and collect photovoltaic power generation information that is delivered from the plurality of data collection devices 300. In a small-scale photovoltaic system 1, the high-level server 400 may not separately exist and the data collection device 300 may also function as the higher server.

An administrator may effectively manage and control a corresponding system, when operating a large-scale photovoltaic system through the higher server 400. The higher server 400 may control both the lower data collection device 300 and the photovoltaic device 100, and by collecting data from a plurality of photovoltaic devices, it is possible to compare the generation of each of the photovoltaic devices 100 and control malfunction.

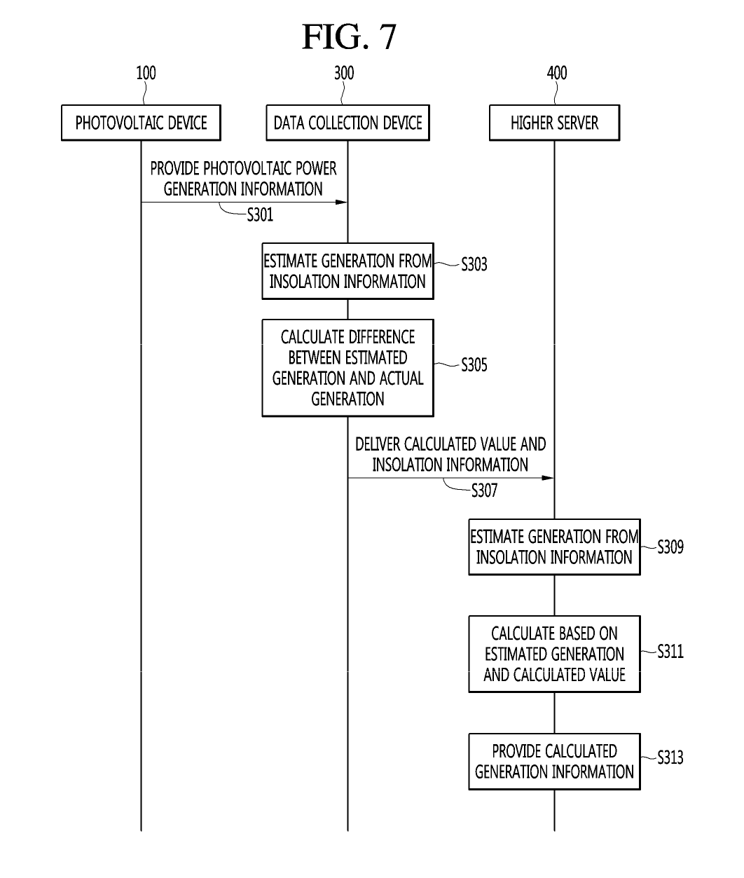

In the following, a photovoltaic monitoring method according to an embodiment is described with reference to FIGS. 7 to 13.

FIG. 7 is a flowchart of the process of transmitting/receiving data for monitoring in a photovoltaic system according to an embodiment.

The photovoltaic device 100 first transmits photovoltaic power generation information to the data collection device 300 in step S301. The photovoltaic power generation information may be photovoltaic generation that the data collection device 300 collects from the inverter 103 or temperature information that the data collection device receives from the temperature sensor. Also, it may also be insolation information collected from an insolation sensor, and besides, various pieces of data required for photovoltaic power generation may be included in the photovoltaic power generation information.

The data collection device 300 estimates generation information based on insolation data among various pieces of data related to photovoltaic power generation from the photovoltaic device 100, in step S303. In particular, since the insolation information may be collected from the photovoltaic device 100 and photovoltaic generation absolutely depends on the light of the sun, it may be seen through the empirical rule that there is a close connection between generation data and the insolation. Based on generation accumulated in the storage unit, the control unit 315 in the data collection device 300 may compare the collected insolation with generation data accumulated in the storage unit 317 to estimate photovoltaic generation.

In an embodiment, the control unit 315 may determine, as estimated generation, the average value of generation according to the insolation for the recent certain period. For example, when the certain period is fixed for a week, the storage unit 317 may store the average value of the insolation and the average value of generation in units of a week. In this case, the control unit 315 may determine, as estimated generation, average generation that corresponds to average insolation closest to the received insolation value.

In another embodiment, the control unit 315 may determine, as estimated generation, generation that matches closest insolation data, among most recent data. For example, the storage unit 317 may store two or more pieces of generation data corresponding to the same insolation. In this case, the control unit 315 may select most recent generation data among two or more pieces of generation data corresponding to the same insolation to determine estimated generation.

In still another embodiment, the control unit 315 may determine the estimated generation in consideration of an average value for the certain period to some extent, based on most recent data.

The above-described estimation step may also be performed by the system control unit 115 of the photovoltaic device 100, when the data collection device 300 is included in the photovoltaic device 100.

The control unit 315 calculates the difference between the estimated generation and actual generation in step S305. In particular, the control unit 315 calculates a value that is obtained by the subtracting of the estimated generation from the actual photovoltaic generation that is received from the inverter.

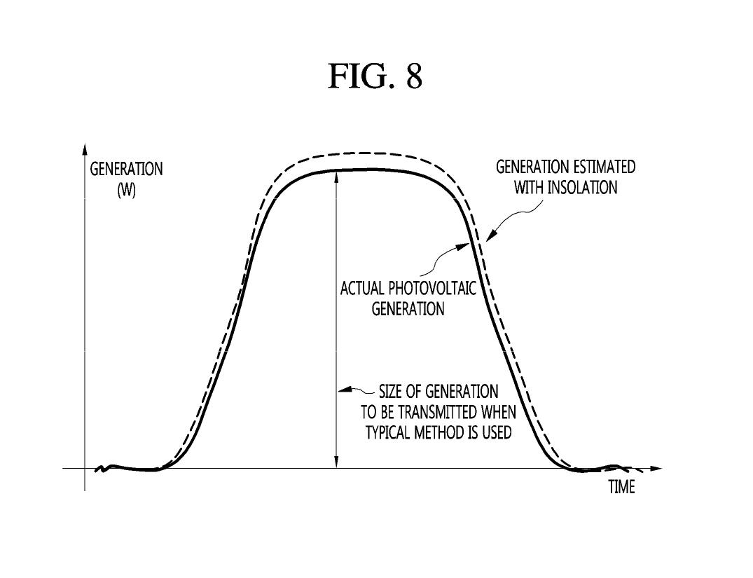

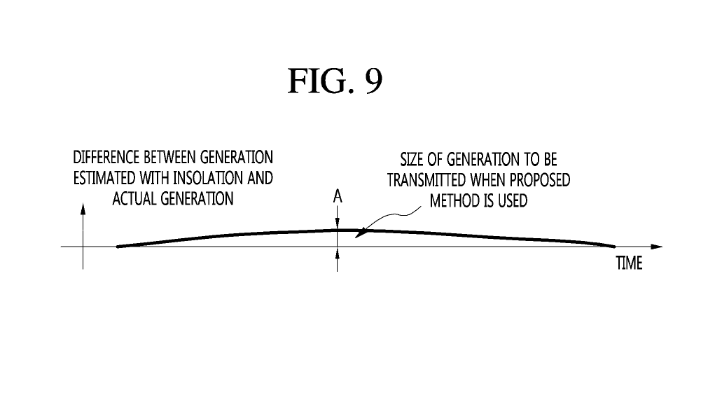

This step is described with reference to FIGS. 8 and 9.

FIG. 8 is a graph that represents how a data collection device typically delivers photovoltaic generation to a higher server.

As shown in FIG. 8, insolation and generation have no choice but to have an immediate connection, due to the characteristic of photovoltaic power generation that absolutely depends on the light of the sun. However, the whole of actual photovoltaic generation has been typically delivered to the higher server 400 irrespective of estimated insolation. In this case, there may be no big problem when there are a small number of solar inverters 103, but in the case of a higher server to which the photovoltaic device 100 including a large-scale solar inverter 103 is connected, there may be a significantly large amount of data when data received from each photovoltaic device 100 is synthesized.

In this case, when the whole of actual generation is transmitted as shown in FIG. 8, it is apprehended that there is a loss of data while big data is transmitted at one time and a cost required for transmitting the big data may also be excessively spent.

On the contrary, according to an embodiment, by using estimated generation that may be seen from accumulated data, a difference A from actual generation is calculated and only the difference A is transmitted to the higher server, as shown in FIG. 9. Thus, since the data collection device does not need to transmit the whole of generation as shown in FIG. 8, an amount of data to be transmitted may sharply decrease.

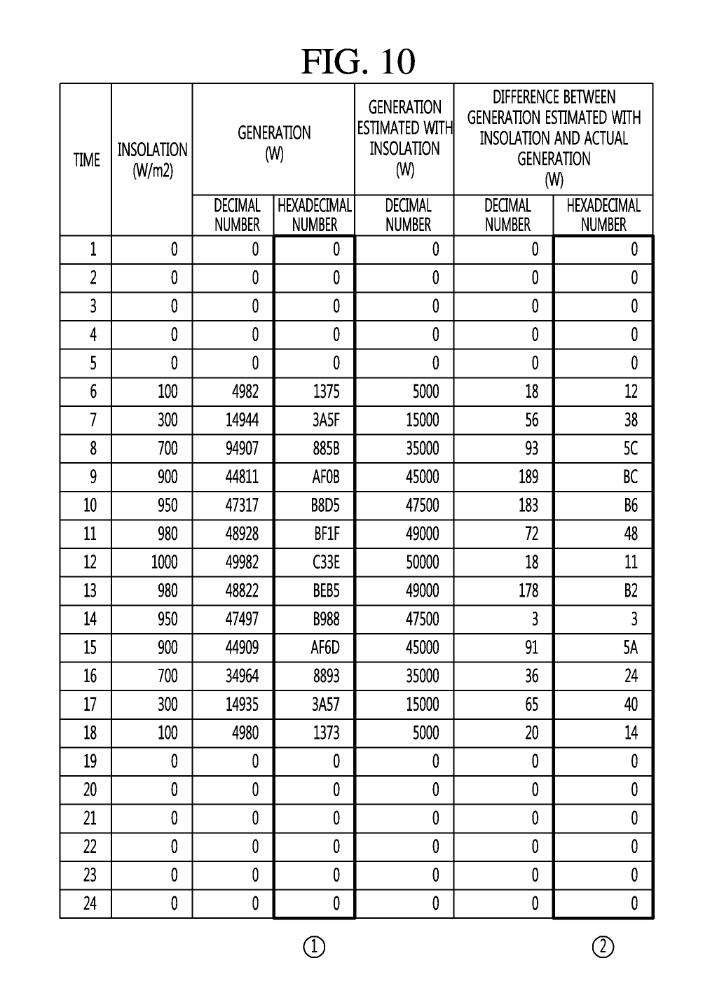

FIGS. 8 and 9 are described in detail with reference to FIG. 10.

FIG. 10 is a diagram that represents daily generation in a table.

Referring to FIG. 10, it may be seen that insolation data exists from 6:00 to 18:00 for which the sun is up, and that generation data may exist according to the insolation data. Thus, it may be seen through the data that generation is directly associated with an increase/decrease in insolation and varies correspondingly, and it may be seen that it is possible to estimate the generation from the insolation.

It may be seen that the generation is a four-digit number when it is expressed in hexadecimal as organized on \textcircled{1} in FIG. 10. Since data transmission is typically performed digitally, it is possible to express in binary and in order for a human being to easily recognize, values are expressed in hexadecimal that is easily converted from binary. However, it may be seen that values \textcircled{2} that are represented by the subtracting of actual generation from estimated generation are binary numbers when expressed in hexadecimal.

Thus, when the generation \textcircled{1} is transmitted as it is, four bytes are needed for data transmission, but when only the difference from the estimated generation is transmitted, two bytes that are half are needed for transmission and thus it is possible to decrease an amount of data to be transmitted by half

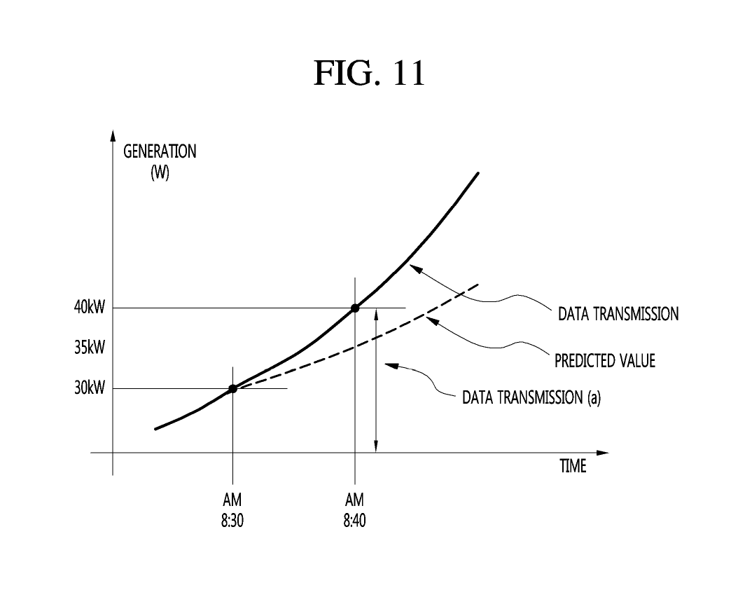

FIGS. 11 to 13 are graphs that compare the above-described transmission method with a typical method.

FIG. 11 represents a typical transmission method and the data collection device 300 delivers the whole of actual generation a data to the higher server 400.

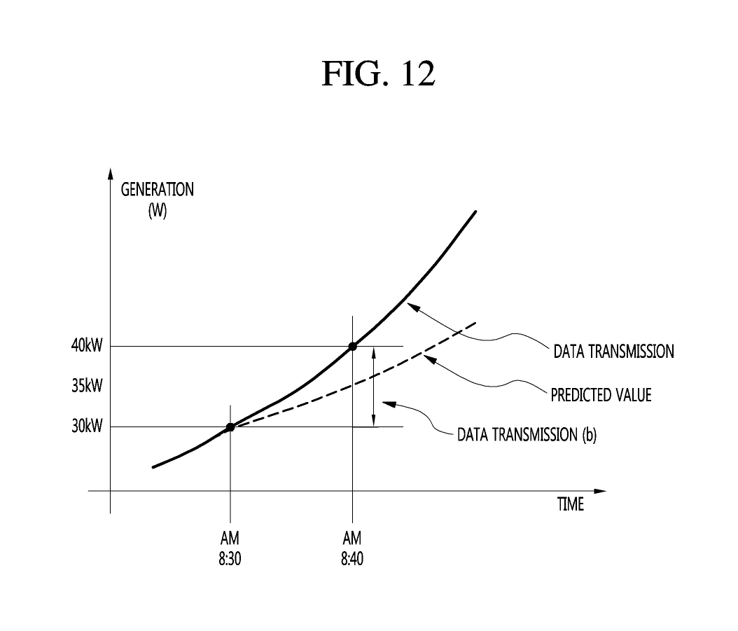

FIG. 12 represents a transmission method according to an embodiment, and the data collection device 300 delivers, to the higher server 400, only a difference b from actual generation over time.

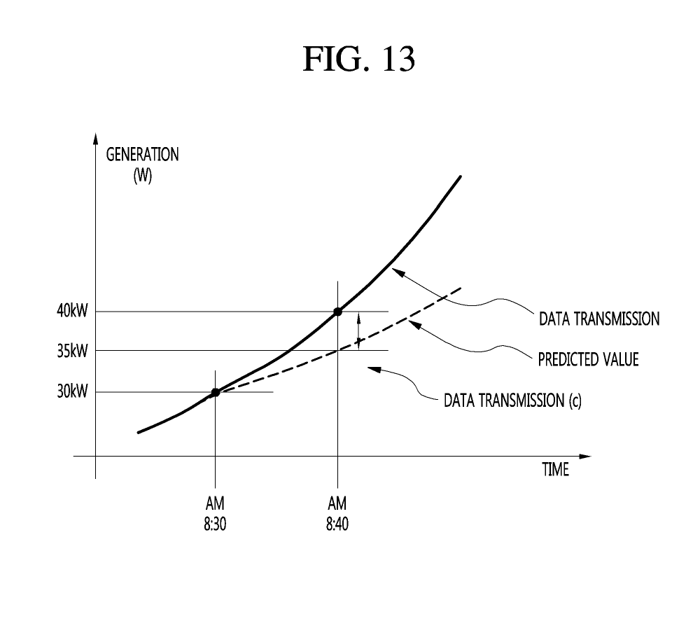

FIG. 13 represents a transmission method according to another embodiment, and the data collection device 300 delivers, to the higher server 400, only a difference c between estimated generation and actual generation.

The method in FIG. 12 may decrease in amount of data to be transmitted when compared to the method in FIG. 11, but has no choice but to relatively increase in amount of data when compared to the method in FIG. 13. Thus, it may be seen that the method of delivering data to the higher server by using estimated generation described in the embodiment is a safe method that may save data.

Refer back to FIG. 7.

The data collection device 300 delivers a difference between estimated generation and actual generation and insolation information to the higher server in step S307. As described above, it is possible to decrease an amount of data by half when compared to a typical method, by transmitting only the difference, not the whole data. In particular, the photovoltaic device 100 and the data collection device 300 are typically disposed close to each other or included in the photovoltaic device 100. Thus, the photovoltaic device 100 is wired to the data collection device in most cases. Thus, transmitting the whole of actual generation is relatively easy in most cases in comparison to delivering to the higher server 400 that depends on wireless communication in most cases.

However, the data collection device 300 and the higher sever 400 are disposed away from each other in most cases, and thus when data is transmitted from the data collection device 300 to the higher server 400, there is a need for a method of minimizing an amount of data to be transmitted. Therefore, the data collection device 300 in an embodiment delivers only estimated generation and a difference along with insolation to the higher server 400.

The higher server 400 estimates generation from received insolation information in step S309. The higher server 400 also accumulates generation information corresponding to insolation and thus it is possible to estimate generation as in the data collection device 300 when the insolation information is received. The method of estimating photovoltaic generation from insolation has been described above.

The higher server 400 applies the received difference to estimated generation to calculate actual generation in step S311. What a user and client really desire to know in the photovoltaic system 1 is generation and not insolation and the higher server 400 calculates actual generation in order to provide corresponding information.

In an embodiment, the higher server 400 and the data collection device 300 may also estimate generation according to temperature information, not insolation.

In another embodiment, the higher server 400 and the data collection device 300 may also estimate generation according to weather information. This case has no choice but to estimate generation having lower accuracy when compared to temperature or insolation information. The above method may be applied when the insolation sensor or temperature sensor of the photovoltaic device 100 is out of order.

In still another embodiment, when it is difficult to receive even weather information, the higher server 400 and the data collection device 300 may estimate actual generation based on the recently accumulated photovoltaic generation. In this case, the data collection device 300 may calculate estimated generation based on accumulated data and transmit, to the higher server 400, a period for which referenced data has been collected, to decrease an amount of data.

The higher server 400 provides calculated actual generation to a user or client in step S313. The provided actual generation may be provided along with estimated generation and a factor that has determined the estimated generation.

The above-described data collection device 300 may be a component in the photovoltaic device 100 or may be a component that replaces the higher server 400.

In another embodiment, the data collection device 300 may deliver the whole generation to the higher server 400 when it is determined that the difference between the received actual generation and the estimated generation is equal to or higher than a certain level. For example, when data exceeding the coverage of accumulated data is received due to extreme weather, it is possible to transmit the whole data to the higher server 400.

In still another embodiment, the data collection device 300 may deliver, to the higher server 400, a difference calculated from fundamental generation according to region information setting. For example, since in the case of a power generation device installed in a desert region, there is a little change in temperature and insolation all the year over, it is possible to calculate the difference from actual generation based on fundamental generation without estimating generation each time based on corresponding region information. In other words, the data collection device 300 may determine, as estimated generation, fundamental generation according to set region information.

When delivering data related to photovoltaic generation to the higher server, it is possible to deliver only insolation information and a difference from estimated generation that are fundamentally delivered, even without delivering the whole data to minimize an amount of data to be delivered.

Also, it is possible to minimize an amount of data to be delivered to the higher server to easily receive data from a photovoltaic device that is installed in a region where it is difficult to communicate.

Also, since an amount of data to be delivered decreases, it is possible to minimize a cost due to the usage of a communication network.

The characteristics, structures, and effects described in the embodiments above are included in at least one embodiment but are not limited to one embodiment. Furthermore, the characteristic, structure, and effect illustrated in each embodiment may be combined or modified for other embodiments by a person skilled in the art. Thus, it would be construed that contents related to such a combination and such a variation are included in the scope of embodiments.

Embodiments are mostly described above. However, they are only examples and do not limit the present disclosure. A person skilled in the art may appreciate that many variations and applications not presented above may be implemented without departing from the essential characteristic of embodiments. For example, each component particularly represented in embodiments may vary. In addition, it should be construed that differences related to such a variation and such an application are included in the scope of the present disclosure defined in the following claims.

What is claimed is:

1. A data collection device comprising:
a receiver receiving, from a photovoltaic device, generation that absorbed solar energy is converted into electrical energy, and photovoltaic power generation related information;
a control unit determining estimated generation based on the photovoltaic power generation related information received from the receiver, and determining a specific value based on the estimated generation and received actual generation;
a storage unit storing photovoltaic power generation data that comprises the generation and the photovoltaic power generation related information; and
a transmitter transmitting, to an external device, the specific value determined by the control unit and the photovoltaic power generation related information.

2. The data collection device according to claim 1, wherein the control unit determines estimated generation from the photovoltaic power generation data accumulated in the storage based on any one of insolation information and temperature information that are included in the photovoltaic power generation related information.

3. The data collection device according to claim 2, wherein the storage unit stores accumulated generation data that comprises insolation data and generation data corresponding to the insolation data, and
the control unit determines, as estimated generation, photovoltaic generation corresponding to the photovoltaic power generation related information among the accumulated generation data.

4. The data collection device according to claim 3, wherein the control unit compares the photovoltaic power generation related information and the insolation data that is stored in the storage unit, and determines, as estimated generation, generation data corresponding to closest insolation data.

5. The data collection device according to claim 1, wherein the control unit determines, as the specific value, a difference between the received actual generation and estimated generation.

6. The data collection device according to claim 1, further comprising an output unit that displays the determined estimated generation and the received actual generation.

7. The data collection device according to claim 1, wherein the control unit transmits a whole of the actual generation to the external device through the transmitter, when a difference between the determined estimated generation and the received actual generation is equal to or larger than a specific value.

8. A photovoltaic system comprising:
a photovoltaic device absorbing and converting solar energy into electrical energy;
a data collection device determining estimated generation based on photovoltaic power generation related information received from the photovoltaic device, and determining a specific value based on the estimated generation and received actual generation; and
an external device determining photovoltaic generation based on the photovoltaic power generation related information and the specific value that are received from the data collection device.

9. The photovoltaic system according to claim 8, wherein the external device estimates photovoltaic generation based on the photovoltaic power generation related information received from the data collection device, and calculates the estimated photovoltaic generation and the specific value to determine photovoltaic generation.

10. The photovoltaic system according to claim 8, wherein the data collection device delivers a whole of photovoltaic generation received from the photovoltaic device to the external device, when the specific value has a size equal to or larger than a certain value.

11. The photovoltaic system according to claim 8, wherein the data collection device determines, as estimated generation, fundamental generation according to set region information.
